(19) United States
(12) Patent Application Publication
(10) Pub. No.: US 2026/0233353 A1
(43) Pub. Date: Aug. 13, 2026

(54) WAFER LAPPING DEVICE AND CONTOL METHOD THEREOF

(71) Applicant: SK SILTRON CO., LTD., Gumi-si, Gyeongsangbuk-do (KR)

(72) Inventors: Myeong Bo SON, Gumi-si (KR); Dae Wook KIM, Gumi-si (KR); Ho Yong LEE, Gumi-si (KR); Jae Pyo LEE, Gumi-si (KR)

(21) Appl. No.: 19/160,725

(22) PCT Filed: May 2, 2023
(86) PCT No.: PCT/KR2023/005980

§ 371 Date: Aug. 28, 2025

(30) Foreign Application Priority Data
Mar. 30, 2023 (KR) 10-2023-0042171

(51) Int. Cl. B24B 37/005; B24B 37/04; H10P 72/00

(52) U.S. Cl. CPC B24B 37/005; B24B 37/042; H10P 72/0428

(57) ABSTRACT

A wafer lapping device may include a lower platen, an upper platen disposed on the lower platen in conjunction with the lower platen to lap a wafer, a cylinder configured to move the upper platen up and down via a rod, a detection target part configured to descend together with the upper platen, a plurality of position sensors configured to detect the detection target part that descends together with the upper platen to detect a descending position of the upper platen, a displacement sensor configured to detects the detection target part that descends together with the upper platen to detect a descending displacement of the upper platen, and a controller configured to control a descending speed of the upper platen based on the descending displacement of the upper platen and the descending position of the upper platen.

### TECHNICAL FIELD

The present invention relates to a wafer lapping device and a control method therefor.

### BACKGROUND ART

A wafer is widely used as a material for manufacturing a semiconductor device and generally refers to a single-crystal silicon thin plate made from polycrystalline silicon as a raw material.

The wafer is manufactured by growing polycrystalline silicon into a single-crystal silicon ingot, followed by a slicing process to cut the silicon ingot into a wafer shape, a lapping process to uniformize the wafer thickness and flatten it, an etching process to remove or mitigate damage caused by mechanical polishing, a polishing process to mirror-finish the wafer surface, and a cleaning process to clean the wafer.

Among these, the lapping process is a process in which a wafer is closely placed between an upper platen and a lower platen, a slurry is introduced between the wafer and the upper/lower platens, and the upper and lower platens are rotated, whereby the wafer undergoes both rotation and revolution, and is lapped by the slurry.

Typically, after the upper platen descends and comes into contact with the lower platen, the upper and lower platens are rotated, whereby the wafer is polished. Since the upper and lower platens rotate at high speed, the rotation should begin only after the upper platen has contacted the lower platen in order to prevent a wipe-out phenomenon, in which the wafer detaches from the carrier.

Conventionally, the lower and upper platens are rotated according to a descending time set in the recipe. However, the actual descending time of the upper platen may vary in each run due to environmental factors or internal issues. Accordingly, the descending time set in the recipe may differ from the actual descending time of the upper platen. In other words, the actual descending time of the upper platen may be longer or shorter than the descending time set in the recipe.

A situation where the actual descending time of the upper platen is longer than the descending time set in the recipe means that the upper platen descends later than expected. In such a case, when the upper and lower platens begin to rotate before the upper platen comes into contact with the lower platen, a wipe-out phenomenon may occur in which wafers housed in a plurality of carriers are dislodged. When the wipe-out phenomenon occurs, both the wafers and the carriers may be damaged due to collisions between them. Additionally, a significant amount of time is required to replace the affected carriers and clean the upper and lower platens.

A situation where the actual descending time of the upper platen is shorter than the descending time set in the recipe means that the upper platen descends too quickly. In this case, the rapidly descending upper platen may collide with the wafers, causing them to break. When such broken wafers are not properly handled and the polishing process proceeds is performed, fragments from the broken wafers may cause scratches or damage to the polishing surfaces of other wafers, and may also damage surrounding components or equipment.

Therefore, there is a strong need for a device or method capable of precisely and efficiently controlling the descending speed of the upper platen, in order to prevent wipe-out of wafers and to avoid wafer breakage.

### DISCLOSURE

### Technical Problem

The present invention aims to solve the aforementioned and other problems.

Another object of the present invention is to provide a wafer lapping device and a control method thereof capable of preventing wafer wipeout.

Another object of the present invention is to provide a wafer lapping device and a control method thereof capable of preventing wafer breakage.

The technical problems of the present invention are not limited to those described herein and include those that may be understood from the description of the present invention.

### Technical Solution

To achieve the above or other objects, according to a first aspect of the present invention, a wafer lapping device, comprising: a lower platen; an upper platen disposed on the lower platen in conjunction with the lower platen to lap a wafer; a cylinder configured to move the upper platen up and down via a rod; a detection target part configured to descend together with the upper platen; a plurality of position sensors configured to detect the detection target part that descends together with the upper platen to detect a descending position of the upper platen; a displacement sensor configured to detects the detection target part that descends together with the upper platen to detect a descending displacement of the upper platen; and a controller configured to control a descending speed of the upper platen based on the descending displacement of the upper platen and the descending position of the upper platen.

The descending speed of the upper platen may comprise a specific speed of the upper platen in a specific section. The specific section may be a section between a first position at which a lower side of the upper platen is positioned when the detection target part is positioned at the lowest position sensor among the plurality of position sensors and a second position at which the lower side of the upper platen is positioned when the upper platen is in contact with the lower platen.

The controller may determine a point at which a displacement signal detected from the displacement sensor inflects as the second position.

The controller may acquire a descending time of the upper platen based on the descending displacement and the descending position of the upper platen in the specific section, acquire whether the descending time of the upper platen is within a predetermined range, and when the descending time of the upper platen is outside the predetermined range, adjust a weight value so that the descending time of the upper platen is within the predetermined range.

The controller may increase the weight value to reduce the specific speed of the upper platen in the specific section when the descending time of the upper platen is less than a lower limit of the predetermined range.

The controller may decrease the weight value to increase the specific speed of the upper platen in the specific section when the descending time of the upper platen exceeds an upper limit of the predetermined range.

The plurality of position sensors may be installed vertically on a lateral part of the cylinder.

The displacement sensor may be positioned higher than the uppermost position sensor among the plurality of position sensors and is installed between the cylinder and the uppermost position sensor.

The wafer lapping device may comprise a support part to which the plurality of position sensors and the displacement sensor are fastened.

The support part may comprise: a first support configured to fasten a plurality of position sensors installed along the vertical direction; and a second support extending toward the cylinder from an upper side of the first support part, to which the displacement sensor is fastened.

The detection target part may be movable up and down between each of the plurality of position sensors and the cylinder.

According to a second aspect of the embodiment to achieve the above or other objects, a control method for a wafer lapping device comprising a lower platen, an upper platen disposed on the lower platen in conjunction with the lower platen to lap a wafer, and a cylinder configured to move the upper platen up and down via a rod, comprising: detecting a detection target part that descend together with the upper platen to detect a descending position of the upper platen, by the plurality of position sensors; detecting the detection target part that descend together with the upper platen to detect a descending displacement of the upper platen, by the displacement sensor; and controlling a descending speed of the upper platen based on the descending displacement of the upper platen and the descending position of the upper platen.

The descending speed of the upper platen may comprise a specific speed of the upper platen in a specific section. The specific section may be a section between a first position at which a lower side of the upper platen is positioned when the detection target part is positioned at the lowest position sensor among the plurality of position sensors and a second position at which the lower side of the upper platen is positioned when the upper platen is in contact with the lower platen.

The control method of the wafer lapping device may comprise determining a point at which a displacement signal detected from the displacement sensor inflects as the second position.

The control method of the wafer lapping device may comprise: acquiring a descending time of the upper platen based on the descending displacement and the descending position of the upper platen in the specific section, acquiring whether the descending time of the upper platen is within a predetermined range, and when the descending time of the upper platen is outside the predetermined range, adjusting a weight value so that the descending time of the upper platen is within the predetermined range.

The adjusting of the weight value may comprise increasing the weight value to reduce the specific speed of the upper platen in the specific section when the descending time of the upper platen is less than a lower limit of the predetermined range.

The adjusting of the weight value may comprise decreasing the weight value to increase the specific speed of the upper platen in the specific section when the descending time of the upper platen exceeds an upper limit of the predetermined range.

### Advantageous Effects

According to at least one embodiment, during a specific section of each run, a weighting value may be adjusted or corrected based on the descending time of the upper platen, and the descending speed of the upper platen may be controlled during a corresponding section of a subsequent run, thereby preventing wafer wipe-out or wafer breakage.

According to at least one embodiment, wafer breakage can be prevented in advance, thereby reducing wafer loss.

According to at least one embodiment, in the event that wafers are wiped out, production loss caused by the time required to handle the dislodged wafers can be prevented.

Further scope of applicability of the embodiments will become apparent from the detailed description below. However, since various changes and modifications within the spirit and scope of the embodiments will become apparent to those skilled in the art, it should be understood that the detailed description and specific embodiments, such as preferred embodiments, are given by way of example only.

### DESCRIPTION OF DRAWINGS

FIG. 1 is a front view of a wafer lapping device according to an embodiment.

FIG. 2 shows the descending speed according to a plurality of sections, when the upper platen is descended.

FIG. 3 illustrates a case where the lower side of the upper platen is positioned at the fourth position P4, which is the starting position of the fourth section, when the upper platen is descended.

FIG. 4 illustrates a case where the lower side of the upper platen is positioned at the fifth position P5, which is the end position of the fourth section, when the upper platen is descended.

FIG. 5 is a flowchart illustrating a control method of a wafer lapping device according to an embodiment.

FIG. 6 is a flowchart illustrating step S330 of FIG. 5 in detail.

FIG. 7 is a flowchart illustrating steps S420 and S430 of FIG. 6 in detail.

### MODE FOR INVENTION

Hereinafter, embodiments disclosed in this specification will be described in detail with reference to the accompanying drawings. Regardless of the drawing numbers, identical or similar components will be assigned the same reference numerals, and redundant descriptions thereof will be omitted. The suffixes “module” and “part” used in the following description for components are assigned or used interchangeably for ease of description, and do not inherently have distinct meanings or functions. Furthermore, the attached drawings are intended to facilitate understanding of the embodiments disclosed herein, and the technical concepts disclosed herein are not limited by the attached drawings. Furthermore, when an element, such as a layer, region, or substrate, is referred to as being “on” another element, this comprises the possibility that it may be directly on the other element or that other intermediate elements may be present between them.

In the following description, the terms “lapping” and “polishing” may be used interchangeably.

FIG. 1 is a front view of a wafer lapping device according to an embodiment.

Referring to FIG. 1, a wafer lapping device 100 according to an embodiment may comprise a lower platen 110, an upper platen 120, a cylinder 130, a detection target part 160, a plurality of position sensors 171 to 174, a displacement sensor 180, and a controller 200.

The lower platen 110 and/or the upper platen 120 may be formed of cast iron. The lower platen 110 may be fixed. The upper platen 120 may be movable up and down.

A plurality of carriers 5 may be mounted on the lower platen 110. A plurality of wafers 10 may be mounted on the carrier 5.

A sun gear 7 may be installed in the central region of the lower platen 110, and an internal gear 6 may be installed in the peripheral region of the lower platen 110. The outer teeth of the carrier 5 are meshed with the teeth of the sun gear 7 and the internal gear 6, and the upper platen 120 and/or the lower platen 110 may rotate and the carrier 5 may revolve around the sun gear 7. Accordingly, the lower surface and/or the upper surface of the wafer 10 may be polished simultaneously.

After a plurality of wafers 10 are mounted on a plurality of carriers 5, the upper platen 120 may be descended to mesh with the lower platen 110. That is, the upper platen 120 may touch or come into proximity with the lower platen 110. The upper platen 120 meshing with the lower platen 110 or touching or coming into proximity with the lower platen 110 may be referred to as matching. After the matching between the upper platen 120 and the lower platen 110 is completed, slurry may be injected between the upper platen 120 and the lower platen 110 and the lower platen 110 may be rotated, thereby lapping the lower surface and/or the upper surface of the wafer 10. At this time, the upper platen 120 may be fixed or rotated. When the upper platen 120 is rotated, the rotation direction of the upper platen 120 and the rotation direction of the lower platen 110 may be opposite to each other, but is not limited thereto.

The upper platen 120 may be movable up and down. The upper platen 120 may be movable up and down by using the cylinder 130 via the rod 135. The rod 135 may be referred to as a shaft or an arm shaft. For example, when air is discharged from the cylinder 130, the rod 135 may be descended. In this instance, the upper platen 120 fastened to the rod 135 may be descended. For example, when air is injected into the cylinder 130, the rod 135 may be raised and the upper platen 120 fastened to the rod 135 may be raised. By the operation of the cylinder 130, the upper platen 120 may be descended to start the lapping process, and may be raised after the lapping process is completed.

The upper platen 120 may comprise a first upper platen 140 and a second upper platen 145. The second upper platen 145 may be fastened to the first upper platen 140 via a connection wire 150. A plurality of first pulleys (not illustrated) may be installed along the outer perimeter of the first upper platen 140, and a plurality of second pulleys (not illustrated) may be installed along the outer perimeter of the second upper platen 145. The first pulleys and the second pulleys may not vertically overlap. That is, the first pulleys and the second pulleys may be installed alternately. For example, the first pulley may be installed clockwise on the first upper platen 140, and then the second pulley may be installed on the second upper platen 145. In this manner, the first pulleys and the second pulleys may be installed alternately along the outer perimeters of the first upper platen 140 and the second upper platen 145, respectively, in a clockwise direction.

The upper platen 120 may comprise a connection part 121. The connection part 121 may be installed on the upper side of the second upper platen 145. A rod 135 may be fixedly fastened to the connection part 121. Accordingly, as the rod 135 moves up and down by using the cylinder 130, the upper platen 120 fixed to the rod 135 may be also movable up and down.

Before the lapping process, the connection wire 150 may be adjusted so that the first upper platen 140 remains horizontal with respect to the second upper platen 145. That is, before the lapping process, the connection wire 150 may be adjusted and fixed so that the length of the connection wire 150 between the first upper platen 140 and the second upper platen 145 becomes the same along the perimeter of each of the first upper platen 140 and the second upper platen 145.

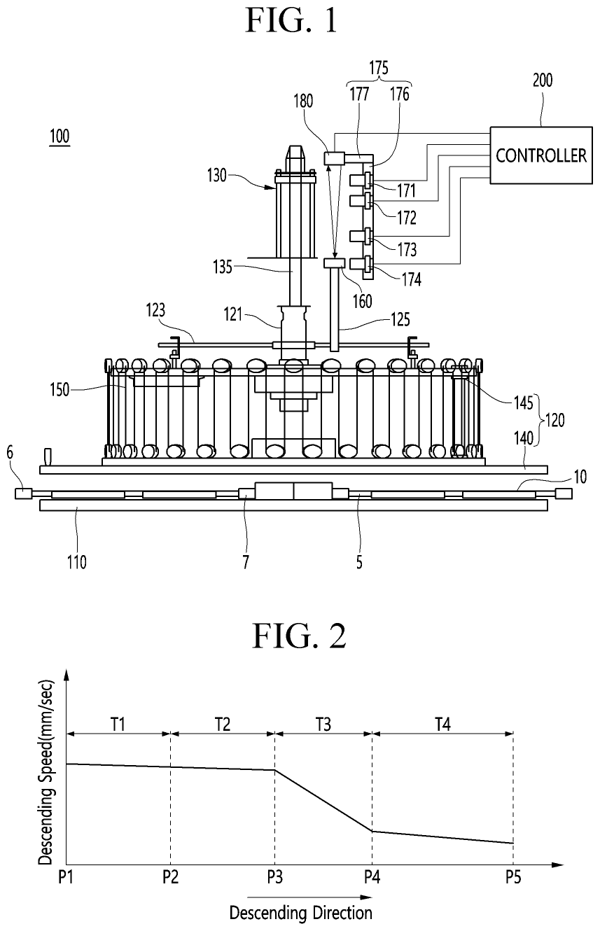

Meanwhile, the detection target part 160 may be movable up and down together with the upper platen 120. The detection target part 160 may be movable up and down between each of the plurality of position sensors 171 to 174 and the cylinder 130. Since the detection target part 160 is movable up and down together with the upper platen 120, the detection target part 160 is detected, thereby detecting the position of the upper platen 120, specifically the position of the lower side of the upper platen 120, or acquiring the matching point between the upper platen 120 and the lower platen 110, i.e., the fifth position (P5 in FIG. 2) of the fourth section T4. Here, the lower side of the upper platen 120 may be the lower side of the first upper platen 140.

The detection target part 160 may be fixed to the upper platen 120 via the first fixing part 123 and the second fixing part 125. The first fixing part 123 may be installed on the connection part 121 and may be formed to extend horizontally. The second fixing part 125 may be installed on the first fixing part 123 and may be formed to extend vertically. In this instance, the detection target part 160 may be installed on the upper side of the second fixing part 125.

Since the connection part 121 is included in the upper platen 120, when the upper platen 120 is movable up and down, the detection target part 160 fixed to the upper platen 120 via the first fixing part 123 and the second fixing part 125 may be also movable up and down. As will be described later, the detection target part 160 may be detected by a plurality of position sensors 171 to 174 or a displacement sensor 180. For example, the detection target part 160 may comprise, but is not limited to, a reflective member or mirror capable of reflecting light or a laser. The reflective member or mirror may be installed on the upper side and the lateral part of the detection target part 160.

Each of the plurality of position sensors 171 to 174 may detect the detection target part 160 that moves up and down together with the upper platen 120 to detect the descending position of the upper platen 120. The plurality of position sensors 171 to 174 may be disposed along a vertical direction on a lateral part of the cylinder 130. The plurality of position sensors 171 to 174 may comprise a first position sensor 171, a second position sensor 172, a third position sensor 173, and a fourth position sensor 174.

The first position sensor 171, the second position sensor 172, the third position sensor 173, and the fourth position sensor 174 may be disposed along a vertical direction. The first position sensor 171, the second position sensor 172, the third position sensor 173, and the fourth position sensor 174 may be positioned on the same vertical line, but is not limited thereto. The first position sensor 171, the second position sensor 172, the third position sensor 173, and the fourth position sensor 174 may be installed at different intervals along the vertical direction, but is not limited thereto.

For example, the first position sensor 171 may be installed at the highest position, and the second position sensor 172 may be installed at a position lower than the position of the first position sensor 171. The third position sensor 173 may be installed at a position lower than the second position sensor 172, and the fourth position sensor 174 may be installed at a position lower than the third position sensor 173.

When the upper platen 120 descends, a plurality of sections for controlling different descending speeds may be acquired using the plurality of position sensors 171 to 174.

As illustrated in FIG. 2, a first section T1 may be acquired using the first position sensor 171 and the second position sensor 172. That is, when the first position P1 is acquired by the first position sensor 171 and the second position P2 is acquired by the second position sensor 172, the first section T1 may be acquired using the first position P1 and the second position P2. For example, the detection target part 160 may descend together with the upper platen 120. When the detection target part 160 descends and is positioned at the first position sensor 171, the position of the detection target part 160 and/or the position of the lower side of the upper platen 120 may be acquired as the first position P1 by the first position sensor 171. Thereafter, when the upper platen 120 continues to descend, when the detection target part 160 descends past the first position sensor 171 and is positioned at the second position sensor 172, the position of the detection target part 160 and/or the position of the lower side of the upper platen 120 may be acquired as the second position P2 by the second position sensor 172. Accordingly, the first section T1 may be acquired by the first position P1 and the second position P2.

The second section T2 may be acquired by the second position sensor 172 and the third position sensor 173. That is, when the second position P2 is acquired by the second position sensor 172 and the third position P3 is acquired by the third position sensor 173, the section between the second position P2 and the third position P3 may be acquired as the second section T2. As described above, when the detection target part 160 is positioned at the second position sensor 172, the second position P2 may be acquired by the second position sensor 172. Thereafter, when the upper platen 120 continues to descend, the detection target part 160 descends past the second position sensor 172 and is positioned at the third position sensor 173, the position of the detection target part 160 and/or the position of the lower side of the upper platen 120 may be acquired as the third position P3 by the third position sensor 173. Accordingly, the second section T2 may be acquired by the second position P2 and the third position P3.

The third section T3 may be acquired by the third position sensor 173 and the fourth position sensor 174. That is, when the third position P3 is acquired by the third position sensor 173 and the fourth position P4 is acquired by the fourth position sensor 174, the section between the third position P3 and the fourth position P4 may be acquired as the third section T3. As described above, when the detection target part 160 is positioned at the third position sensor 173, the third position P3 may be acquired by the third position sensor 173. Thereafter, when the upper platen 120 continues to descend, the detection target part 160 descends past the third position sensor 173 and is positioned at the fourth position sensor 174, the position of the detection target part 160 and/or the position of the lower side of the upper platen 120 may be acquired as the fourth position P4 by the fourth position sensor 174. Accordingly, the third section T3 may be acquired by the third position P3 and the fourth position P4.

Meanwhile, as will be described later, the fourth position P4 and the fifth position P5 constituting the fourth section T4 may be acquired by the fourth position sensor 174 and the displacement sensor 180, respectively. When the upper platen 120 continues to descend and the detection target part 160 is positioned at the fourth position sensor 174, tracking for the fourth section T4 may begin. For example, when the detection target part 160 is positioned at the fourth position sensor 174, the fourth position P4, which is the starting position of the fourth section T4, may be acquired by the fourth position sensor 174.

Simultaneously, the displacement of the detection target part 160 may be tracked by the displacement sensor 180. The fifth position P5, which is the end position of the fourth section T4, may be acquired by the displacement sensor 180.

As illustrated in FIG. 2, the descending speed of the upper platen 120 may be controlled differently in each of the first section T1, the second section T2, the third section T3, and the fourth section T4. For example, the descending speed of the upper platen 120 in each of the first section T1 and the second section T2 may be high speed. At this time, the descending speeds of the upper platen 120 in each of the first section T1 and the second section T2 may be the same or different. Therefore, by descending the upper platen 120 at high speed during the first section T1 and the second section T2, the tact time of each run may be reduced.

In the third section T3, the descending speed of the upper platen 120 may be gradually decelerated according to the descending position of the upper platen 120, i.e., from the third position P3 to the fourth position P4. Accordingly, in the fourth section T4, the descending speed may be rapidly decelerated from high speed to low speed, thereby preventing the upper platen 120 from shaking or the wafer 10 from colliding with the upper platen 120.

In the fourth section T4, the descending speed of the upper platen 120 may be slow. Although the drawing illustrates the descending speed of the upper platen 120 in the fourth section T4 as being the same, it may also be gradually decelerated. By descending the upper platen 120 at a low speed during the fourth section T4, a collision of the wafer 10 with the upper platen 120 can be prevented. In addition, by ensuring that the lower platen 110′s descending time during the fourth section T4 is within a predetermined range, the lower platen 110 may be rotated at a high speed after the lower platen 110 matches the upper platen 120. Accordingly, a wipe-out phenomenon of the wafer 10 or damage to the wafer 10 caused by the lower platen 110′'s descending time exceeding the predetermined range can be prevented.

Meanwhile, the specific section described in the claims below refers to the fourth section T4, and the first position and the second position of the specific section described in the claims below may refer to the fourth position P4 and the fifth position P5 of the fourth section T4, respectively.

The plurality of position sensors 171 to 174 may each comprise a light-emitting part that emits light and a light-receiving part that receives light, but is not limited thereto.

The displacement sensor 180 may detect the detection target part 160 that moves up and down together with the upper platen 120 to detect the descending displacement of the upper platen 120. For example, the displacement sensor 180 may comprise, but is not limited to, a laser-based displacement sensor 180.

The displacement sensor 180 may be positioned higher than the uppermost position sensor 171 among the plurality of position sensors 171 to 174. The displacement sensor 180 may be installed between the cylinder 130 and the uppermost position sensor 171. The displacement sensor 180 may be installed to face the upper side of the detection target part portion 160. Accordingly, a laser from the displacement sensor 180 may be irradiated in a vertical direction, and the laser reflected by the detection target part portion 160 may be received by the light-receiving part of the displacement sensor 180, thereby detecting the displacement of the detection target part portion 160.

The fifth position (P5 in FIG. 2), which is the end position of the fourth section T4 described above, may be determined as a point where a displacement signal detected from the displacement sensor 180 inflects. When the upper platen 120 continues to descend, the detection target part 160 also descends, so that the displacement signal detected for the detection target part 160 may change. For example, as the detection target part 160 descends, the displacement signal detected for the detection target part 160 may increase. Thereafter, when the upper platen 120 continues to descend and matches the lower platen 110, the upper platen 120 may no longer descend and may stop descending. When the upper platen 120 stops descending, the detection target part 160 also stops descending, so that the displacement signal detected from the displacement sensor 180 may be maintained at the same value. Accordingly, when the displacement signal increases and then remains constant, the inflection point where the increase and then becomes constant may be determined as the fifth position P5, which is the end position of the fourth section T4 described above.

Meanwhile, the plurality of position sensors 171 to 174 and the displacement sensor 180 may be fixedly fastened to a support part 175. The support part 175 may comprise a first support part 176 for fixing the plurality of position sensors 171 to 174 installed in the vertical direction, and a second support part 177 extending from the upper side of the first support part 176 toward the cylinder 130, to which the displacement sensor 180 is fixedly fastened.

The controller 200 may control a descending speed of the upper platen 120 based on a descending displacement of the upper platen 120 and a descending position of the upper platen 120. As described above, the descending position of the detection target part 160 may be detected by the plurality of displacement sensors 180, and the descending displacement of the detection target part 160 may be detected by the displacement sensor 180. In other words, the descending position of the upper platen 120 may be detected by the plurality of displacement sensors 180, and the descending displacement of the upper platen 120 may be detected by the displacement sensor 180.

The controller 200 may control the descending speed of the upper platen 120 differently for each of the plurality of sections acquired according to the descending of the upper platen 120, as illustrated in FIG. 2. The plurality of sections T1 to T4 may be acquired using the plurality of position sensors 171 to 174 and the displacement sensor 180. For example, the first section T1 may be a section between the first position P1 and the second position P2 acquired by the first position sensor 171 and the second position sensor 172, respectively. For example, the second section T2 may be a section between the second position P2 and the third position P3 acquired by the second position sensor 172 and the third position sensor 173, respectively. For example, the third section T3 may be a section between the third position P3 and the fourth position P4 acquired by the third position sensor 173 and the fourth position sensor 174, respectively.

For example, the fourth section T4 may be a section between the fourth position P4 and the fifth position P5 acquired by the fourth position sensor 174 and the displacement sensor 180, respectively. In particular, the fifth position P5 may be determined as a point where a displacement signal detected from the displacement sensor 180 is inflected.

The controller 200 may precisely control the descending speed of the upper platen 120 in the fourth section T4. By controlling the descending time of the upper platen 120 in the fourth section T4 to be within the range set by the recipe, the controller 200 can prevent the wipe-out phenomenon of the wafer 10 or the damage of the wafer 10.

Specifically, the controller 200 may acquire the descending time of the upper platen 120 based on the descending displacement of the upper platen 120 and the descending position of the upper platen 120 in the fourth section T4, acquire whether the descending time of the upper platen 120 is within the range set by the recipe, and when the descending time of the upper platen 120 is outside the predetermined range, adjusts or corrects the weight value so that the descending time of the upper platen 120 is within the predetermined range.

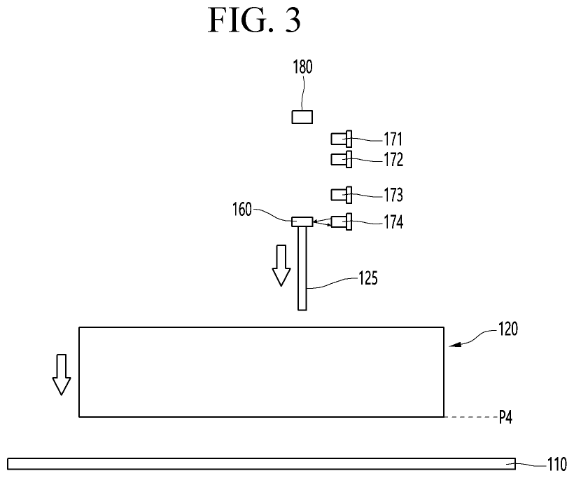

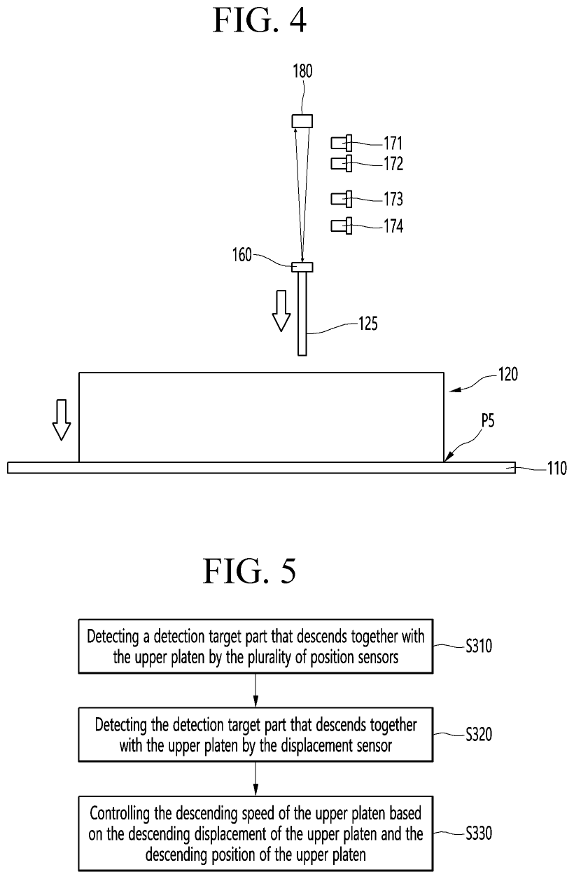

For example, the fourth position P4 of the fourth section T4 may be acquired by the fourth position sensor 174 (FIG. 3), and the fifth position P5 of the fourth section T4 may be acquired by the displacement sensor 180 (FIG. 4).

As illustrated in FIG. 3, when the detection target part 160 is descended together with the upper platen 120 and the detection target part 160 is positioned at the fourth position sensor 174, the position of the detection target part 160 and/or the position of the lower side of the upper platen 120 may be acquired as the fourth position P4 by the fourth position sensor 174. When the detection target part 160 is positioned at the fourth position sensor 174, the displacement sensor 180 may be operated to irradiate the laser in a vertical direction, but is not limited thereto.

The detection target part 160 may descend together with the upper platen 120, and the detection target part 160 may descend toward the lower platen 110 past the fourth position sensor 174. As the detection target part 160 descends, the displacement signal detected from the displacement sensor 180 may change. For example, the displacement signal may increase as the detection target part 160 descends, but is not limited thereto. When the upper platen 120 touches the lower platen 110, the upper platen 120 may no longer descend. In this instance, the displacement signal detected by the displacement sensor 180 may be maintained at the same value. Therefore, a point at which the displacement signal inflects, that is, an inflection point where it increases and then becomes constant, may be determined as the fifth position P5 of the fourth section T4.

Meanwhile, when the descending time of the upper platen 120 is less than the lower limit of the predetermined range, the controller 200 may increase the weight value to reduce the descending speed of the upper platen 120 in the fourth section T4. Furthermore, when the descending time of the upper platen 120 exceeds the upper limit of the predetermined range, the controller 200 may decrease the weight value to increase the descending speed of the upper platen 120 in the fourth section T4.

FIG. 5 is a flowchart illustrating a control method of a wafer lapping device according to an embodiment.

Referring to FIGS. 1 and 5, when a run is first initiated, the upper platen 120 may be descended. That is, the rod 135 may be descended by air discharged from the cylinder 130, and the upper platen 120 fastened to the rod 135 may also be descended.

When the upper platen 120 is descended, the detection target part 160 fastened to the upper platen 120 may also be descended. At this time, the detection target part 160 may be descended between a plurality of position sensors 171 to 174 disposed vertically with the cylinder 130.

The plurality of position sensors 171 to 174 may each detect a detection target part 160 that descends together with the upper platen 120 (S310). The detection target part 160 may descend in a vertical direction along a lateral part of the cylinder 130.

The plurality of position sensors 171 to 174 may each comprise a light-emitting part and a light-receiving part. Light may be irradiated from the light-emitting part of each of the plurality of position sensors 171 to 174 toward the lateral part of the cylinder 130. The amount or intensity of light received by respective light-receiving parts of the plurality of position sensors 171 to 174 may vary depending on whether the detection target part 160 is positioned at each of the position sensors 171 to 174 or not.

In this way, the position of the detection target part 160 or the section between the previous position and the current position of an adjacent detection target part 160 may be acquired based on the received amount of light or light intensity. When the position of the detection target part 160 is acquired, the position of the lower side of the upper platen 120 to which the detection target part 160 is attached may also be acquired. Furthermore, when the section of the detection target part 160 is acquired, the section between the previous position and the current position of the lower side of the upper platen 120 to which the detection target part 160 is attached may be acquired.

Meanwhile, when the upper platen 120 descends, a detection target part 160 fastened to the upper platen 120 may descend in a vertical direction on the lateral part of the cylinder 130. As the detection target part 160, which descends in the vertical direction as described above, passes each of the plurality of position sensors 171 to 174 disposed along the vertical direction, a plurality of positions P1 to P5, as shown in FIG. 2, may be acquired.

For example, when a run begins, the upper platen 120 may be descended to match the lower platen 110, and then the lower platen 110 and/or the upper platen 120 may be rotated at high speed, thereby allowing a plurality of wafers 10 to be polished on the lower platen 110.

The plurality of positions P1 to P5 illustrated in FIG. 2 may be acquired during the process of the upper platen 120 matching the lower platen 110 from the start of the run.

First, when the detection target part 160 descends together with the upper platen 120 by the start of the run, and the detection target part 160 passes the first position sensor 171, the detection target part 160 may be detected by the first position sensor 171. The first position P1 may be detected based on the detection result by the controller 200, that is, the amount or intensity of light reflected by the detection target part 160.

When the detection target part 160 passes the second position sensor 172 via the first position sensor 171, the detection target part 160 may be detected by the second position sensor 172. The second position P2 may be detected based on the detection result by the controller 200, that is, the amount or intensity of light reflected by the detection target part 160. A first section T1 may be acquired by a first position P1 and a second position P2. When the first position P1 is detected, the controller 200 may drive the cylinder 130 so that the upper platen 120 descends at a descending speed set in the recipe, for example, a first descending speed. The upper platen 120 may descend at the first descending speed until the second position P2 is detected. The first descending speed may be high.

Thereafter, when the detection target part 160 passes the third position sensor 173 via the second position sensor 172, the detection target part 160 may be detected by the third position sensor 173. The third position P3 may be acquired based on the detection result by the controller 200, i.e., the amount or intensity of light reflected by the detection target part 160. The second section T2 may be acquired by the second position P2 and the third position P3. When the second position P2 is detected, the controller 200 may drive the cylinder 130 to descend the upper platen 120 at a descending speed set in the recipe, for example, a second descending speed. The upper platen 120 may be descended at the second descending speed until the third position P3 is detected. The second descending speed may be high. The second descending speed may be the same as the first descending speed, but is not limited thereto.

Thereafter, when the detection target part 160 passes the fourth position sensor 174 via the third position sensor 173, the detection target part 160 may be detected by the fourth position sensor 174. The fourth position P4 may be acquired based on the result detected by the controller 200, that is, the amount or intensity of light reflected by the detection target part 160. The third section T3 may be acquired by the third position P3 and the fourth position P4. When the third position P3 is detected, the controller 200 may drive the cylinder 130 so that the upper platen 120 descends at a descending speed set in the recipe, for example, a third descending speed. The upper platen 120 may descend at the third descending speed until the fourth position P4 is detected. The third descending speed may be gradually decelerated to the fourth position P4.

For example, the first position P1 to the fourth position P4 may be the positions of the first position sensor 171 to the fourth position sensor 174, respectively, through which the detection target part 160 passes. For example, the first position P1 to the fourth position P4 may be positions on a lower side of the upper platen 120 when the detection target part 160 is positioned at the first position sensor 171 to the fourth position sensor 174, respectively.

Meanwhile, when the fourth position P4 is detected, the displacement sensor 180 may detect the detection target part 160 that descends together with the upper platen 120 (S320). That is, when the fourth position P4 is detected, the controller 200 may drive the displacement sensor 180 to irradiate a laser toward the detection target part 160. When the detection target part 160 descends past the fourth position P4, the controller 200 may detect a descending displacement of the detection target part 160, i.e., a displacement signal, using the fourth displacement sensor 180.

As the detection target part 160 descends, the displacement signal detected from the detection target part 160 may vary. For example, the displacement signal may increase as the detection target part 160 descends.

Meanwhile, the upper platen 120 may descend and touch the lower platen 110. In other words, the upper platen 120 may match the lower platen 110. In this instance, the detection target part 160 fastened to the upper platen 120 may no longer descend and may stop descending. After the upper platen 120 matches the lower platen 110, the displacement signal for the detection target part 160 may be maintained at a constant value.

Therefore, the controller 200 may track the change in the displacement signal for the detection target part 160 and determine a point at which the displacement signal inflects as the fifth position P5. The fifth position P5 may be the position where the lower side of the upper platen 120 touches the upper side of the lower platen 110.

The fourth section T4 may be acquired by the fourth position P4 and the fifth position P5.

The specific section described in the claims below refers to the fourth section T4, and the first position and the second position of the specific section described in the claims below may refer to the fourth position P4 and the fifth position P5 of the fourth section T4, respectively.

The controller 200 can prevent a wipe-out phenomenon of the wafer 10 or damage to the wafer 10 by controlling the descending speed of the lower platen 110, i.e., the fourth descending speed, in the fourth section T4.

The controller 200 may control the descending speed of the upper platen 120 based on the descending displacement of the upper platen 120 and the descending position of the upper platen 120 (S330).

As described above, the fourth position P4 may be detected using the fourth position sensor 174, and the fifth position P5 may be detected using the displacement sensor 180. The section between the fourth position P4 and the fifth position P5 may be determined as the fourth section T4.

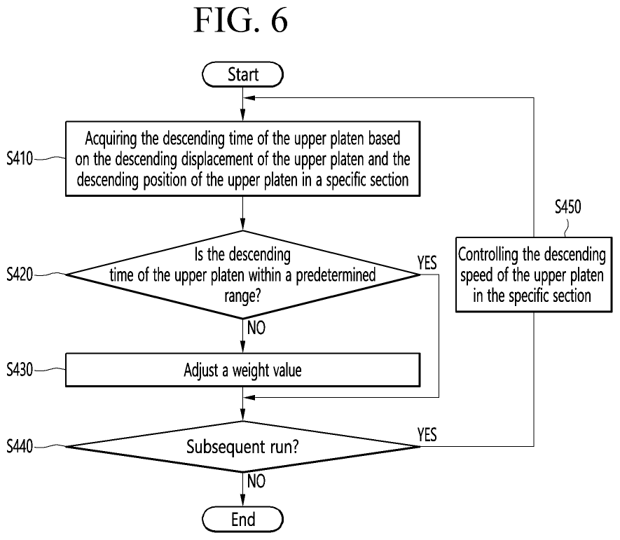

As illustrated in FIG. 6, the controller 200 may acquire the descending time of the upper platen 120 based on the descending displacement of the upper platen 120 and the descending position of the upper platen 120 in a specific section, i.e., the fourth section T4 (S410). That is, the controller 200 may acquire the time taken for the lower side of the upper platen 120 to descend from the fourth position P4 to the fifth position P5 in the fourth section T4.

The controller 200 may determine whether the descending time of the upper platen 120 is within the range set in the recipe (S420).

When the descending time of the upper platen 120 is outside the range set in the recipe, the controller 200 may adjust a weight value to control the descending speed of the upper platen 120 in a subsequent run (S430). The adjusted weight value may be stored in memory or updated in the recipe.

Upon completion of the run, the upper platen 120 may be returned to its original position. That is, the rod 135 may be raised by the air injected into the cylinder 130, and the upper platen 120 fastened to the rod 135 may also be raised. In other words, by the operation of the cylinder 130, the upper platen 120 may be descended to start the lapping process, and after the lapping process is completed, the upper platen 120 may be raised, thereby completing one run.

Meanwhile, when a subsequent run is operated (S440), the controller 200 may control the descending speed of the upper platen 120 so that it is within the range set in the recipe based on the adjusted weight value during the fourth section T4 of a subsequent run (S450). Here, the adjusted weight value may be the weight value adjusted in the previous run, but is not limited thereto. Since the descending speed of the upper platen 120 is controlled so that the descending speed of the upper platen 120 is within the range set in the recipe, the lower platen 110 and/or the upper platen 120 may be rotated at high speed after the upper platen 120 is matched with the lower platen 110, so that wipe-out of the wafer 10 or damage to the wafer 10 can be prevented.

Meanwhile, in S420, when the descending time of the upper platen 120 is within the range set in the recipe, this may mean that the upper platen 120 is matched with the lower platen 110. In this instance, the controller 200 may perform a polishing process on a plurality of wafers 10 on the lower platen 110 by rotating the lower platen 110 and/or the upper platen 120 at high speed.

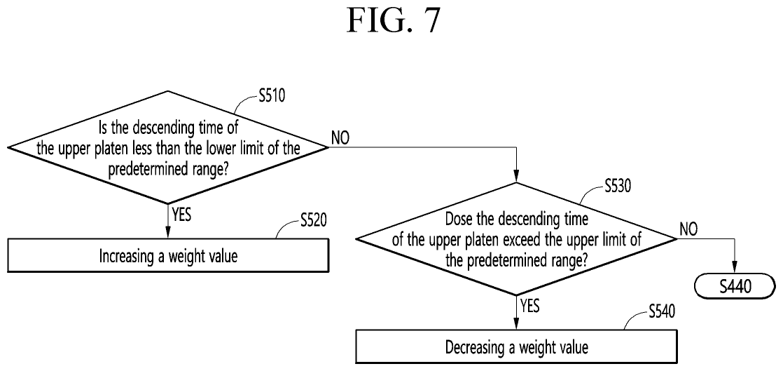

The adjustment of the weight value will be described in detail with reference to FIG. 7.

As illustrated in FIG. 7, when the descending time of the upper platen 120 is outside the range set in the recipe, the controller 200 may determine whether the descending time of the upper platen 120 is less than the lower limit of the range set in the recipe (S510). For example, when the range set in the recipe is 28 to 32 seconds, the controller 200 may determine whether the descending time of the upper platen 120 is less than 28 seconds.

When the descending time of the upper platen 120 is less than a lower limit of a range set in a recipe, the controller 200 may increase a weight value (S520). The weight value may be increased by a predetermined value. The weight value may be increased in proportion to the amount by which the descending time of the upper platen 120 deviates from the lower limit of the range set in the recipe. For example, when the descending time of the upper platen 120 is 27 seconds, the weight value may be +1. For example, when the descending time of the upper platen 120 is 26 seconds, the weight value may be +2.

By the increased weight value as described above, the descending speed of the upper platen 120 during a fourth section T4 in a subsequent run may be reduced, so that the descending time of the upper platen 120 may be within the range set in the recipe.

When the descending time of the upper platen 120 is outside the range set in the recipe, the controller 200 may determine whether the descending time of the upper platen 120 exceeds the upper limit of the range set in the recipe (S530). For example, when the range set in the recipe is 28 to 32 seconds, the controller 200 may determine whether the descending time of the upper platen 120 exceeds 32 seconds.

When the descending time of the upper platen 120 exceeds an upper limit of a range set in the recipe, the controller 200 may decrease a weight value (S540). The weight value may be decreased by a predetermined value. The weight value may be decreased in proportion to the amount by which the descending time of the upper platen 120 deviates from the upper limit of the range set in the recipe. For example, when the descending time of the upper platen 120 is 33 seconds, the weight value may be −1. For example, when the descending time of the upper platen 120 is 34 seconds, the weight value may be −2.

By the decreased weight value as described above, the descending speed of the upper platen 120 during a fourth section T4 in a subsequent run may be increased, so that the descending time of the upper platen 120 may be within a range preset in the recipe.

According to an embodiment, the weight value may be adjusted based on the descending time of the upper platen 120 during a fourth section T4 of each run, and the descending speed of the upper platen 120 may be controlled during the fourth section T4 of the subsequent run, so that wipe-out of the wafer 10 or damage to the wafer 10 can be prevented.

The above detailed description should not be construed as limiting in any respect and should be considered illustrative. The scope of the embodiments should be determined by a reasonable interpretation of the appended claims, and all changes within the scope of equivalents of the embodiments are included within the scope of the embodiments.

1. A wafer lapping device, comprising:
a lower platen;
an upper platen disposed on the lower platen in conjunction with the lower platen to lap a wafer;
a cylinder configured to move the upper platen up and down via a rod;
a detection target part configured to descend together with the upper platen;
a plurality of position sensors configured to detect the detection target part that descends together with the upper platen to detect a descending position of the upper platen;
a displacement sensor configured to detects the detection target part that descends together with the upper platen to detect a descending displacement of the upper platen; and
a controller configured to control a descending speed of the upper platen based on the descending displacement of the upper platen and the descending position of the upper platen.

2. The wafer lapping device of claim 1, wherein the descending speed of the upper platen comprises a specific speed of the upper platen in a specific section, and
wherein the specific section is a section between a first position at which a lower side of the upper platen is positioned when the detection target part is positioned at the lowest position sensor among the plurality of position sensors and a second position at which the lower side of the upper platen is positioned when the upper platen is in contact with the lower platen.

3. The wafer lapping device of claim 2, wherein the controller is configured to determine a point at which a displacement signal detected from the displacement sensor inflects as the second position.

4. The wafer lapping device of claim 2, wherein the controller is configured:
to acquire a descending time of the upper platen based on the descending displacement and the descending position of the upper platen in the specific section,
to acquire whether the descending time of the upper platen is within a predetermined range, and
when the descending time of the upper platen is outside the predetermined range, to adjust a weight value so that the descending time of the upper platen is within the predetermined range.

5. The wafer lapping device of claim 4, wherein the controller is configured to increase the weight value to reduce the specific speed of the upper platen in the specific section when the descending time of the upper platen is less than a lower limit of the predetermined range.

6. The wafer lapping device of claim 5, wherein the controller is configured to decrease the weight value to increase the specific speed of the upper platen in the specific section when the descending time of the upper platen exceeds an upper limit of the predetermined range.

7. The wafer lapping device of claim 1, wherein the plurality of position sensors are installed vertically on a lateral part of the cylinder.

8. The wafer lapping device of claim 7, wherein the displacement sensor is positioned higher than the uppermost position sensor among the plurality of position sensors and is installed between the cylinder and the uppermost position sensor.

9. The wafer lapping device of claim 8, comprising a support part to which the plurality of position sensors and the displacement sensor are fastened.

10. The wafer lapping device of claim 9, wherein the support part comprises:
a first support configured to fasten a plurality of position sensors installed along the vertical direction; and
a second support extending toward the cylinder from an upper side of the first support part, to which the displacement sensor is fastened.

11. The wafer lapping device of claim 8, wherein the detection target part is configured to be movable up and down between each of the plurality of position sensors and the cylinder.

12. A control method for a wafer lapping device comprising a lower platen, an upper platen disposed on the lower platen in conjunction with the lower platen to lap a wafer, and a cylinder configured to move the upper platen up and down via a rod, comprising:
detecting a detection target part that descend together with the upper platen to detect a descending position of the upper platen, by the plurality of position sensors;
detecting the detection target part that descend together with the upper platen to detect a descending displacement of the upper platen, by the displacement sensor; and
controlling a descending speed of the upper platen based on the descending displacement of the upper platen and the descending position of the upper platen.

13. The control method of the wafer lapping device according to claim 12, wherein the descending speed of the upper platen comprises a specific speed of the upper platen in a specific section, and
wherein the specific section is a section between a first position at which a lower side of the upper platen is positioned when the detection target part is positioned at the lowest position sensor among the plurality of position sensors and a second position at which the lower side of the upper platen is positioned when the upper platen is in contact with the lower platen.

14. The control method of the wafer lapping device according to claim 13, comprising determining a point at which a displacement signal detected from the displacement sensor inflects as the second position.

15. The control method of the wafer lapping device according to claim 13, comprising:
acquiring a descending time of the upper platen based on the descending displacement and the descending position of the upper platen in the specific section,
acquiring whether the descending time of the upper platen is within a predetermined range, and
when the descending time of the upper platen is outside the predetermined range, adjusting a weight value so that the descending time of the upper platen is within the predetermined range.

16. The method for controlling a wafer lapping device according to claim 15, wherein the adjusting of the weight value comprises increasing the weight value to reduce the specific speed of the upper platen in the specific section when the descending time of the upper platen is less than a lower limit of the predetermined range.

17. The method for controlling a wafer lapping device according to claim 16, wherein the adjusting of the weight value comprises decreasing the weight value to increase the specific speed of the upper platen in the specific section when the descending time of the upper platen exceeds an upper limit of the predetermined range.
